(19) United States
(12) Patent Application Publication
(10) Pub. No.: US 2008/0054386 A1
(43) Pub. Date: Mar. 6, 2008

(54) Recessed color filter array and method of forming the same

(75) Inventor: Salman Akram, Boise, ID (US)

Correspondence Address: DICKSTEIN SHAPIRO LLP, 1825 EYE STREET, NW, WASHINGTON, DC, 20006, US

(73) Assignee: MICRON TECHNOLOGY, INC.

(21) Appl. No.: 11/513,246

(22) Filed: Aug. 31, 2006

(51) Int. Cl. H01L 31/0232; H01L 21/00

(52) U.S. Cl. 257/432; 438/740; 438/98; 438/70; 257/440

(57) ABSTRACT

A recessed color filter array using patterned metal as an etch stop and a method of forming the same. In one embodiment, at least one metal etch stop is formed in a semiconductor dielectric layer at the same time as the formation of one or more layers of metal interconnect elements, thereby reducing the number of necessary process steps and reducing costs. The etch stop may be formed at any layer where other metal elements are present.

### FIELD OF THE INVENTION

Embodiments of an embodiment of the invention relate to semiconductor devices and methods of making such devices.

### BACKGROUND OF THE INVENTION

As imaging arrays are used in smaller and smaller applications, there is a need to decrease the stack height of the imaging array, requiring the use of a recessed array, i.e., the pixel array is recessed in a substrate to prevent the color filter and lens elements in some cases from extending above a desired upper limit of the stack. Forming a recessed array typically requires the use of an etch stop to accurately form the array.

FIGS. 1A and 1B show simplified, partial cross sections of a prior art imager 100 having a conventional etch stop 105 formed therein. Imager 100 includes a substrate 101 supporting an array of pixels 102, and a dielectric layer 103 (e.g., an oxide) comprising a plurality of individual dielectric layers supporting associated metal interconnects 104 for connecting to associated circuitry (not shown) and an etch stop 105, typically formed of nitride material, for example, silicon nitride (Si₃N₄). The formation of the metal interconnects 104 and the etch stop 105 requires separate processing steps because they are formed of different materials, increasing fabrication cost.

FIG. 1B shows the formation of a plurality of recesses, or wells 110, each corresponding to a pixel 102, through the etch stop 105 using known techniques. The etch stop 105 initially stops the formation of each well 110, and a different known process removes the etch stop material at the bottom of each well 110. FIG. 1C shows the formation of a color filter 109 in each well 110 and placement of a lens 108 over each color filter array 109.

A major drawback of employing a conventional etch stop 105 is the additional process steps involved, including formation of the etch stop 105 and the well 110 as separate processes from forming other structures of the imager 100. In addition to the additional processing steps, conventional nitride etch stops have several other disadvantages, such as e.g., preventing efficient alloying, which can result in the annealing of defective transistors.

Accordingly, there is a need for an improved etch stop material and process, which simplifies fabrication for semiconductor imager devices.

### BRIEF DESCRIPTION OF THE DRAWINGS

FIG. 1A is a cross sectional view of an imager employing a conventional etch stop.

FIG. 1B is a cross sectional view of the semiconductor device of FIG. 1A at a subsequent stage of fabrication.

FIG. 1C is a cross sectional view of the semiconductor device of FIG. 1B at a subsequent stage of fabrication.

FIG. 2A is a cross sectional view of an imager employing a metal etch stop according to an embodiment of the invention.

FIG. 2B is a cross sectional view of the semiconductor device of FIG. 2A at a subsequent stage of fabrication.

FIG. 2C is a cross sectional view of the semiconductor device of FIG. 2B at a subsequent stage of fabrication.

FIG. 3A is a cross sectional view of an imager employing a metal etch stop according to another embodiment of the invention.

FIG. 3B is a cross sectional view of the semiconductor device of FIG. 3A at a subsequent stage of fabrication.

FIG. 3C is a cross sectional view of the semiconductor device of FIG. 3B at a subsequent stage of fabrication.

FIG. 4A is a cross sectional view of an imager employing a metal etch stop according to another embodiment of the invention.

FIG. 4B is a cross sectional view of the semiconductor device of FIG. 4A at a subsequent stage of fabrication.

FIG. 4C is a cross sectional view of the semiconductor device of FIG. 4B at a subsequent stage of fabrication.

FIG. 4D is a cross sectional view of the semiconductor device of FIG. 4B at an alternate subsequent stage of fabrication.

FIG. 4E is a cross sectional view of the semiconductor device of FIG. 4D at a subsequent stage of fabrication.

FIG. 5A is a cross sectional view of an imager employing a metal etch stop according to another embodiment of the invention.

FIG. 5B is a cross sectional view of the semiconductor device of FIG. 5A at a subsequent stage of fabrication.

FIG. 5C is a cross sectional view of the semiconductor device of FIG. 5B at a subsequent stage of fabrication.

FIG. 5D is a cross sectional view of the semiconductor device of FIG. 5B at an alternate subsequent stage of fabrication.

FIG. 5E is a cross sectional view of the semiconductor device of FIG. 5D at a subsequent stage of fabrication.

FIG. 6A is a cross sectional view of an imager employing a metal etch stop according to another embodiment of the invention.

FIG. 6B is a cross sectional view of the semiconductor device of FIG. 6A at a subsequent stage of fabrication.

FIG. 6C is a cross sectional view of the semiconductor device of FIG. 6B at a subsequent stage of fabrication.

FIG. 7A is a cross sectional view of an imager employing a metal etch stop according to another embodiment of the invention.

FIG. 7B is a cross sectional view of the semiconductor device of FIG. 7A at a subsequent stage of fabrication.

FIG. 7C is a cross sectional view of the semiconductor device of FIG. 7B at a subsequent stage of fabrication.

FIG. 8 illustrates a top-down view of an imager employing a metal etch stop according to an embodiment of the invention.

FIG. 9 illustrates a computer system having an imager employing a metal etch stop according to an embodiment of the invention.

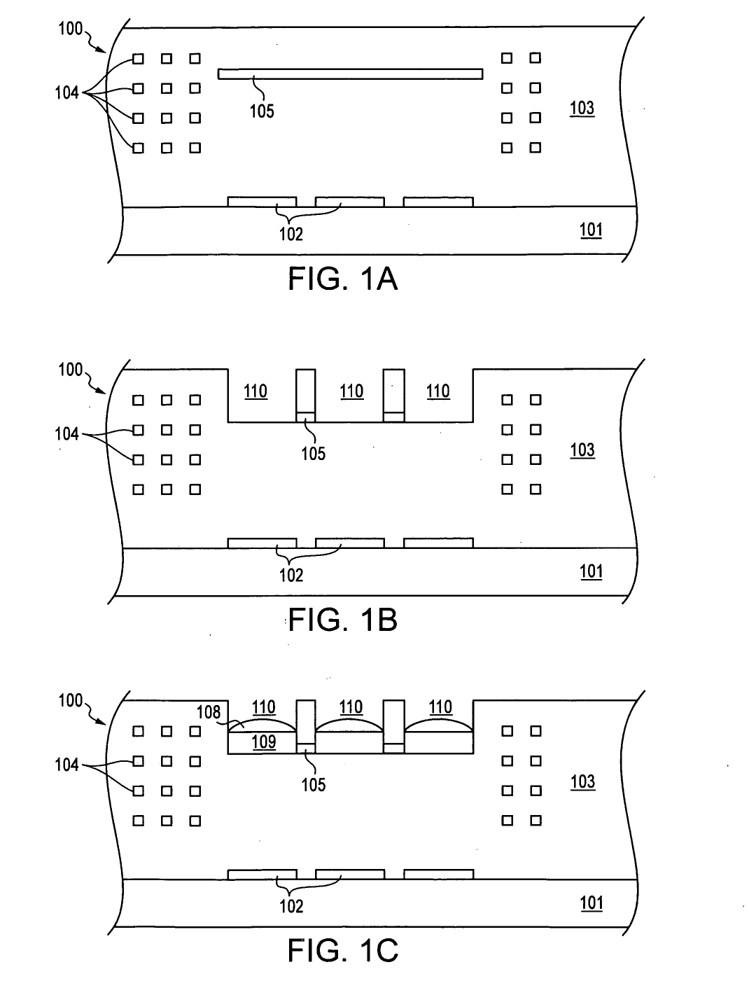

### DETAILED DESCRIPTION OF PREFERRED EMBODIMENTS

In the following detailed description, reference is made to various specific embodiments in which the invention may be practiced. These embodiments are described with sufficient detail to enable those skilled in the art to practice them, and it is to be understood that other embodiments may be employed, and that structural and electrical changes may be made.

The term “substrate” used in the following description may include any semiconductor-based structure that has a semiconductor surface. The term should be understood to include silicon, silicon-on insulator (SOI), silicon-on sapphire (SOS), doped and undoped semiconductors, epitaxial layers of silicon supported by a base semiconductor foundation, and other semiconductor structures. The semiconductor need not be silicon-based. The semiconductor could be silicon-germanium, germanium, or gallium arsenide or other semiconductor materials. When reference is made to a “substrate” in the following description, previous process steps may have been utilized to form regions or junctions in or on the base semiconductor or foundation.

Embodiments described herein provide a recessed color filter array using a patterned metal layer as an etch stop and a method of forming the same. In an example embodiment, at least one metal etch stop is formed in a semiconductor dielectric layer at the same time as the formation of one or more layers of metal interconnect elements or light block elements, thereby reducing the number of necessary process steps and reducing costs. The etch stop may be formed at any layer where other metal elements are present. In most embodiments, the metal etch stop does not contact the metal interconnects or light block elements in the final product. However, the metal etch stop or a portion thereof can be connected to associated metal interconnect or light block elements, if desired.

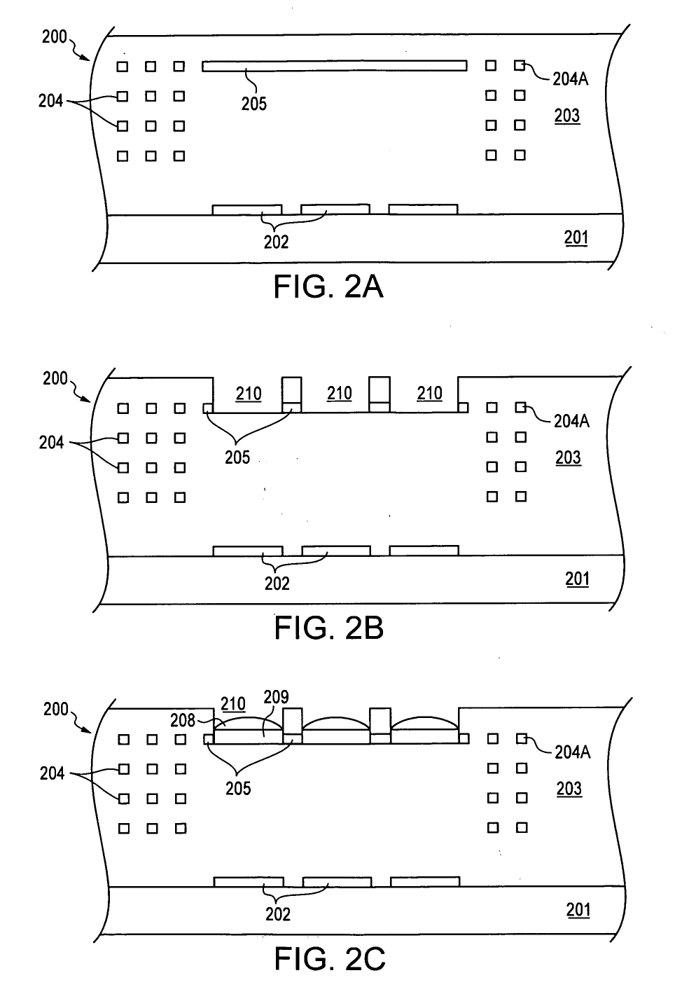

Referring now to the drawings, where like elements are designated by like reference numerals, FIGS. 2A-2C illustrate the formation of a recessed color filter array according to an embodiment of the invention. Imager 200 includes a substrate 201 comprising an array of pixels 202, and a dielectric layer 203 comprising a plurality of individual dielectric layers and associated metal layers forming metal interconnects 204 for connection with associated circuitry (not shown) and an etch stop 205. In this embodiment, the etch stop 205 is formed as a patterned metal of the same metal material as the interconnects 204. It is formed at the same time as the uppermost layer 204A of metal interconnects 204.

As shown in FIGS. 2B and 2C, a plurality of wells 210 are formed through the etch stop 205. A known first etch process forms a portion of the well through the dielectric layer 203 to the upper surface of the etch stop 205, which initially stops the formation of the wells 210. A different known second etch process removes the metal etch stop material 205 so the bottom of the wells 210 stop on an upper surface of dielectric layer 203. A selective metal dry etch can be employed to achieve this result. A color filter 209 and lens 208 are deposited in each well 210. The wells 210 may be formed by any known semiconductor etching technique.

In the illustrated embodiment, there are four layers of metal interconnects 204 at different levels of the imager 200. The metal etch stop 205 may be formed at any one or more of these levels, and at the same time as the respective metal interconnect layer is formed. In the illustrated embodiment, the etch stop 205 is formed at a fourth, top metal interconnect layer. In this and other subsequent embodiments, for simplicity, the cross section of the imager contains three recesses in one horizontal direction, but the number can be larger or smaller depending on the desired imager array. Typically, one recess corresponds to each pixel and is formed directly above the pixel in order to maximize the collection of light.

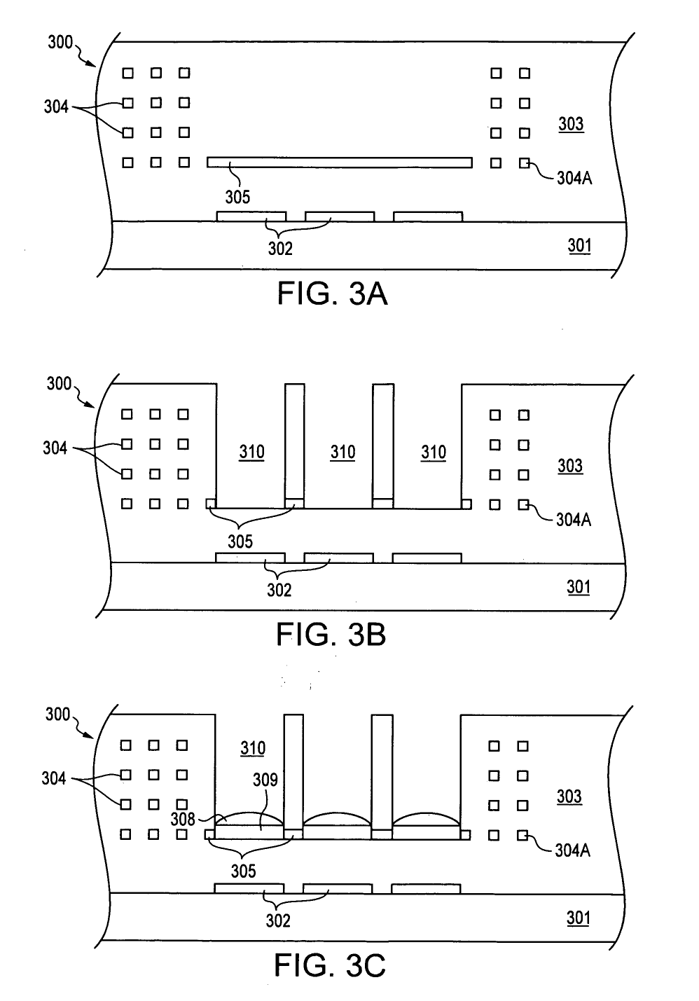

FIGS. 3A-3C illustrate the formation of a recessed color filter array according to another embodiment. Imager 300 includes a substrate 301 comprising an array of pixels 302, a dielectric layer 303, metal interconnects 304 for connection with associated circuitry and an etch stop 305. In this embodiment, the etch stop 305 is formed at the same time as the lower most layer 304A containing interconnects 304.

As shown in FIGS. 3B and 3C, a plurality of wells 310 is formed through the etch stop 305 and stops at the etch stop 305, and a color filter 309 and lens 308 are formed in the well using known techniques. In this embodiment, the metal etch stop 305 is formed at first, bottom layer 304A of the interconnects 304.

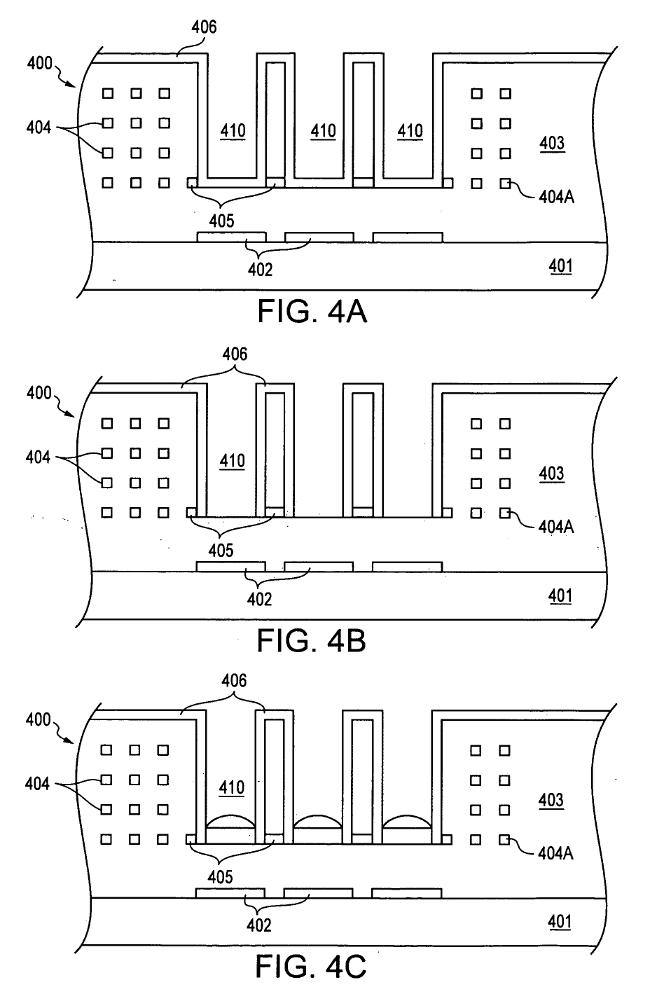

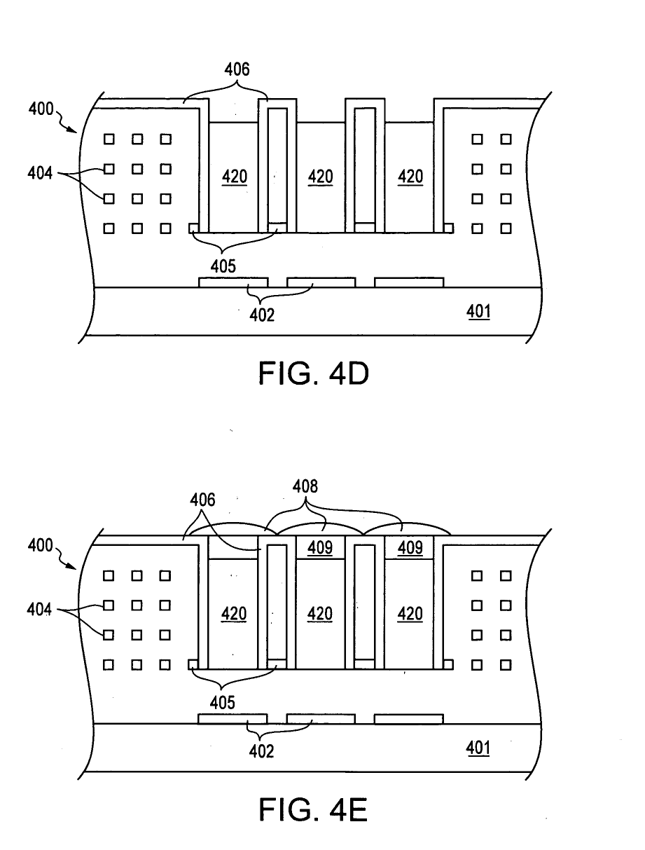

FIGS. 4A-4C illustrate the formation of a recessed color filter array 409 according to another embodiment of the invention. Imager 400 includes a substrate 401 comprising an array of pixels 402, and a dielectric layer 403 comprising metal interconnects 404 for connection with associated circuitry and an etch stop 405 at the first, bottom layer. A plurality of wells 410 is formed through the etch stop (formed at first, bottom layer 404A; see FIG. 3B above) and a metal layer 406 is deposited on the inside surface of the wells 410.

As shown in FIG. 4B, the bottom surface of metal layer 406 at the bottom of each well 410 is removed. A color filter 409 and lens 408 are deposited in each well 410, as shown in FIG. 4C. In this embodiment, the lens 408 may be omitted. The metal layer 406 shields the dielectric layer 403 from incoming light, preventing absorption of light by the oxide layer 403, and reflects light back toward the each respective pixel 402.

In an alternative embodiment shown by FIG. 4D-4E, a transparent insulator 420 having a different index of refraction than dielectric layer 403 may be deposited in the well prior to deposition of the color filter 409. In this embodiment, the lens 408 may cap the well 410 and a portion of the surrounding metal layer 406.

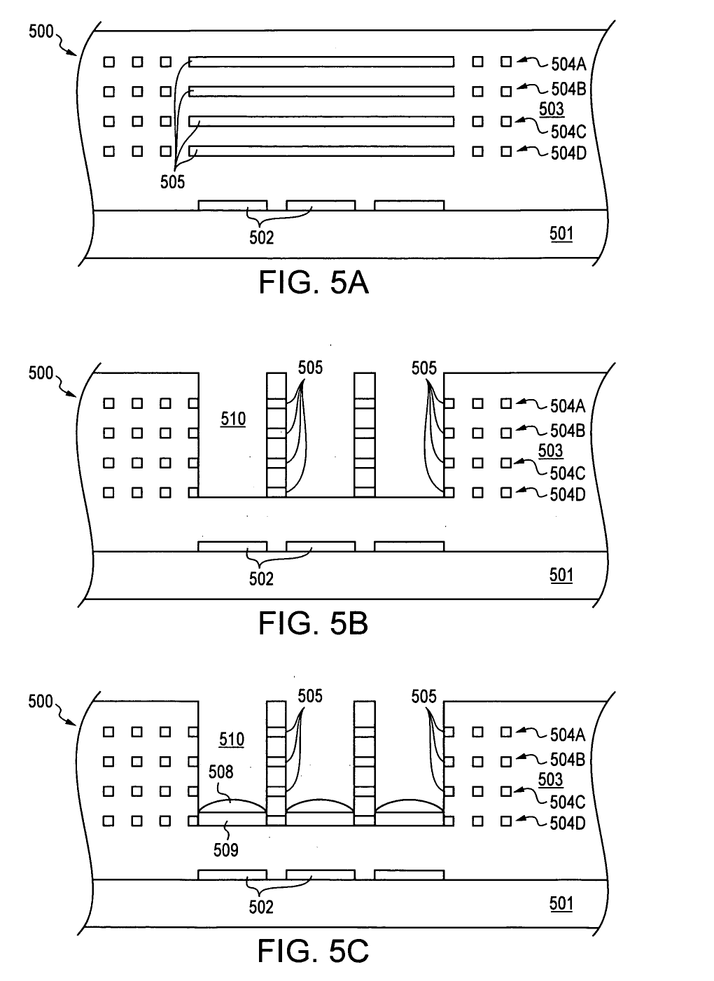

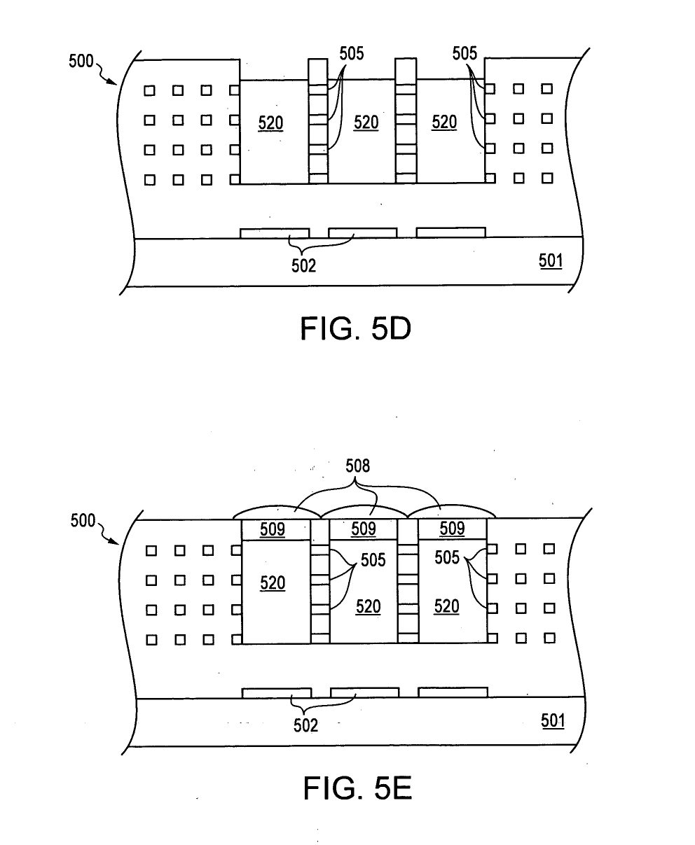

FIGS. 5A-5C illustrate the formation of a recessed color filter array 509 according to another embodiment of the invention. Imager 500 includes a substrate 501 comprising an array of pixels 502, and a dielectric layer 503 comprising metal interconnects 504 for connection with associated circuitry and a plurality of etch stops 505 formed at all four metal interconnect layers 504. As shown in FIG. 5B, a plurality of wells 510 is formed through the etch stops 505, and a color filter array 509 and lens 508 are deposited in each well 510, shown in FIG. 5C.

In an alternative embodiment shown by FIG. 5D-5E, a transparent insulator 520 having a different index of refraction than dielectric layer 503 may be deposited in the well prior to deposition of the color filter 509. In this embodiment, the lens 508 may cap the well 510 and a portion of the surrounding metal layer 506.

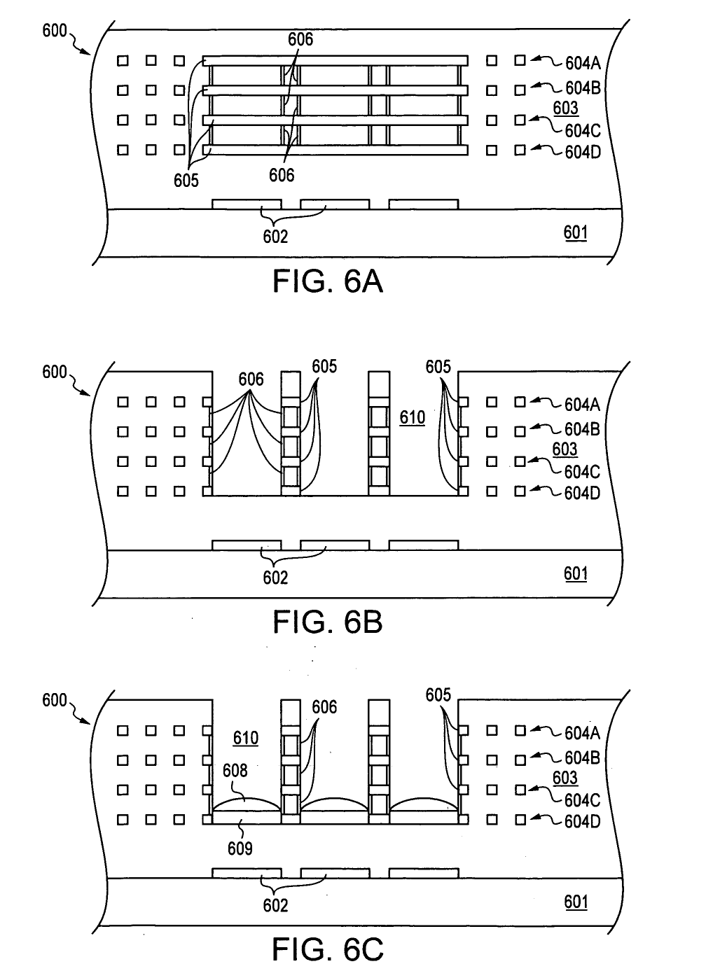

FIGS. 6A-6C illustrate the formation of a recessed color filter array 609 according to another embodiment of the invention. Similar to the embodiment of FIG. 5A-5C, imager 600 includes a substrate 601 comprising an array of pixels 602, and a dielectric layer 603 comprising metal interconnects 604 for associated circuitry and a plurality of etch stops 605 formed at all four metal interconnect layers 604.

In addition, metal walls 606 are formed vertically between each etch stop 605. As shown in FIG. 6B, when each well 610 is formed through the etch stops 605, the metal walls 606 cover the otherwise exposed portions of the dielectric layer 603 within each well 610, thereby reflecting light toward the respective pixels 602 and preventing absorption of light by the dielectric layer 603. A color filter array 609 and lens 608 are deposited in each well 610, shown in FIG. 6C.

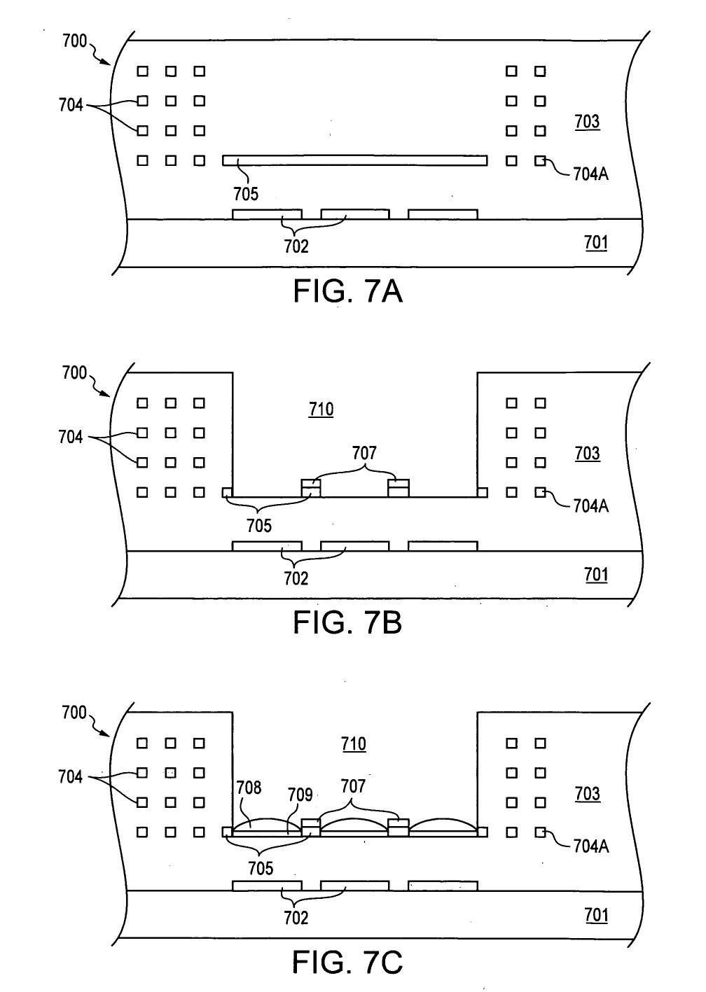

FIGS. 7A-7C illustrate the formation of a recessed color filter array 709 according to another embodiment of the invention. Similar to the embodiment of FIG. 3A-3C, imager 700 includes a substrate 701 comprising an array of pixels 702, and a dielectric layer 703 comprising metal interconnects 704 for associated circuitry and an etch stop 705 formed at the first, bottom interconnect layer 704.

As shown in FIG. 7B, in this embodiment, a single well 710 is formed to the depth of the top surface of the etch stop 705. The surface is then masked and patterned (not shown) and a plurality of recesses are then formed within and through the etch stop 705. In this embodiment, the mask material 707 is retained, but it may alternately be removed after formation of the recesses. In this embodiment, these recesses are square or rectangular, but they can be any desired shape or configuration. The recesses are associated with individual pixels or groups of pixels of the pixel array 702.

As shown in FIG. 7C, individual color filters or color filter arrays 709 are deposited in the individual recesses, followed by individual lenses 708. The remaining etch stop portions 705 reduce optical crosstalk among pixels 702 by reflecting light to the appropriate lenses 708 and color filters 709.

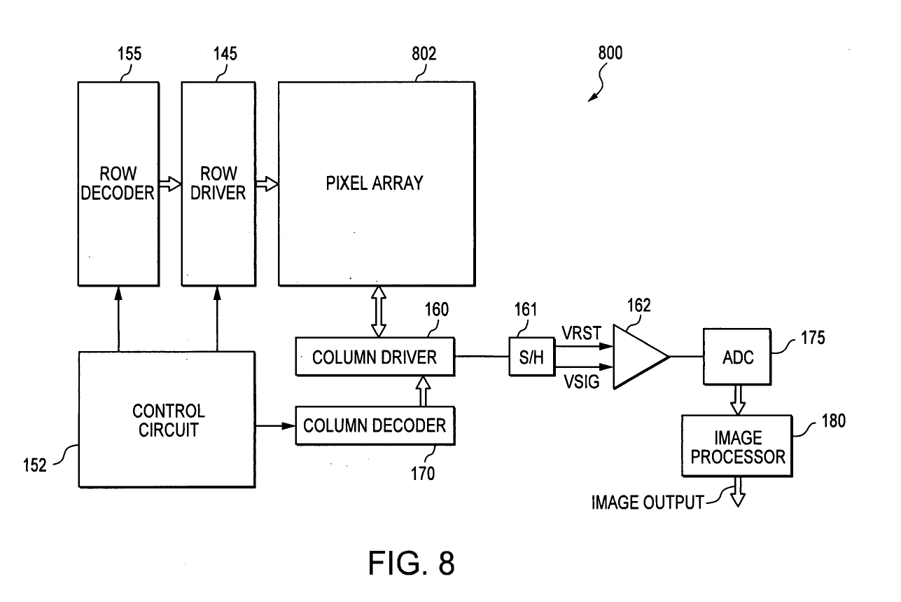

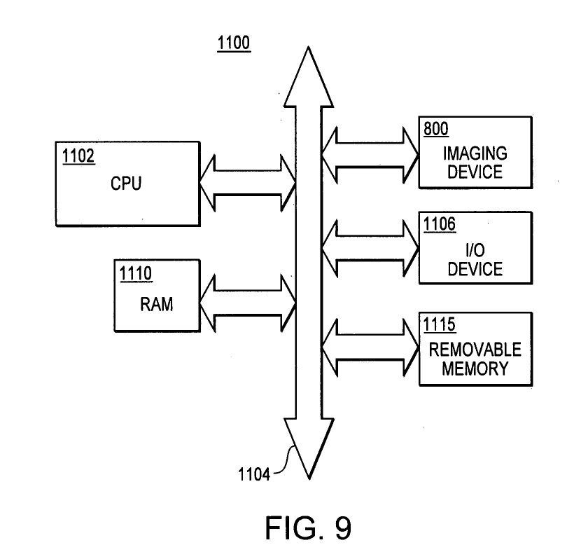

FIG. 8 illustrates a block diagram of a CMOS imager 800 constructed in accordance with one of or a combination of the embodiments described above. The imaging device 800 contains an array of pixels 802 and employs a metal etch stop according to one of or a combination of the embodiments shown in FIGS. 2-7. Attached to the pixel array 802 is signal processing circuitry for controlling the pixel array 802. The pixel cells of each row in array 802 are all turned on at the same time by a row select line, and the pixel cells of each column are selectively output by respective column select lines. A plurality of row select and column select lines are provided for the entire array 802. The row lines are selectively activated by a row driver 145 in response to row address decoder 155. The column select lines are selectively activated by a column driver 160 in response to column address decoder 170. Thus, a row and column address is provided for each pixel cell.

The CMOS imager 800 is operated by a timing and control circuit 152, which controls address decoders 155, 170 for selecting the appropriate row and column lines for pixel readout. The control circuit 152 also controls the row and column driver circuitry 145, 160 such that they apply driving voltages to the drive transistors of the selected row and column lines. The pixel column signals, which typically include a pixel reset signal Vᵣₛₜ and a pixel image signal V_{sig}, are output to column driver 160, on output lines, and are read by a sample and hold circuit 161. Vᵣₛₜ is read from a pixel cell immediately after the pixel cell's floating diffusion region is reset. V_{sig} represents the amount of charges generated by the photosensitive element of the pixel cell in response to applied light during an integration period. A differential signal (Vᵣₛₜ−V_{sig}) is produced by differential amplifier 162 for each readout pixel cell. The differential signal is digitized by an analog-to-digital converter 175 (ADC). The analog to digital converter 175 supplies the digitized pixel signals to an image processor 180, which forms and outputs a digital image.

FIG. 9 illustrates a processor system 1100 that includes an imaging device 800 constructed in accordance with an embodiment of the invention. As discussed above, the imaging device 800 contains an array of pixels 802 and employs a metal etch stop according to any embodiment or a combination of the embodiments shown in FIGS. 2-7. The system 1100 has digital circuits that could include image sensor devices. Without being limiting, such a system could include a computer system, camera system, scanner, machine vision, vehicle navigation, video phone, surveillance system, auto focus system, star tracker system, motion detection system, image stabilization system, and other image sensing and/or processing system.

The system 1100, for example a camera system, generally comprises a central processing unit (CPU) 1102, such as a microprocessor, that communicates with an input/output (I/O) device 1106 over a bus 1104. Imaging device 800 also communicates with the CPU 1102 over the bus 1104. The processor system 1100 also includes random access memory (RAM) 1110, and can include removable memory 1115, such as flash memory, which also communicates with CPU 1102 over the bus 1104. Imaging device 800 may be combined with a processor, such as a CPU, digital signal processor, or microprocessor, with or without memory storage on a single integrated circuit or on a different chip than the processor.

The above description and drawings are only to be considered illustrative of embodiments which achieve the features and advantages of an embodiment of the invention. Modification and substitutions to specific process conditions and structures can be made without departing from the spirit and scope of an embodiment of the invention. Accordingly, the invention is not to be considered as being limited by the foregoing description and drawings, but is only limited by the scope of the appended claims.

1. A method of forming a semiconductor structure comprising a substrate and a dielectric layer, said method comprising the steps of:
forming at least one horizontal patterned metal layer in said dielectric layer, said metal layer comprising an etch stop located over a fixed array area; and
wherein the etch stop is also located over at least one interconnect for connection to electronic circuitry.

2. The method of claim 1, further comprising the acts of
forming a well having vertical walls in said dielectric layer over at least one pixel, said well extending through said etch stop; and
forming at least one optical element in said well allowing at least partial transmission of light between said at least one pixel and the upper vertical limit of said semiconductor structure.

3. (canceled)

4. The method of claim 2, further comprising the act of forming a metal layer over said vertical walls of said well.

5. The method of claim 2, further comprising the formation of at least one vertical metal frame within said dielectric layer and in contact with said etch stop such that when said well is formed, said metal frame forms the vertical walls of the well.

6. The method of claim 1, further comprising the steps of:
forming a well having vertical walls into said dielectric layer;
forming an array of recesses through said etch stop; and
forming at least one optical element in each of said recesses.

7. A semiconductor device comprising:
a semiconductor substrate;
a dielectric layer formed over the substrate, said dielectric layer comprising:
at least one patterned metal layer comprising at least one interconnect for circuitry and an etch stop.

8. The semiconductor device of claim 7, further comprising:
a well having vertical walls in said dielectric layer, said well extending through said etch stop; and
at least one optical element deposed in said well for at least partial transmission of light between a pixel array and the upper vertical limit of said semiconductor structure.

9. (canceled)

10. (canceled)

11. The device of claim 8, wherein said vertical walls comprise at least one vertical metal frame within said dielectric and in contact with said etch stop.

12. The device of claim 7, further comprising:
a well having vertical walls in said dielectric layer;
an array of recesses in said etch stop; and
at least one optical element in each of said recesses for at least partial transmission of light between a pixel array and the upper vertical limit of said semiconductor structure.

13. A method of forming a semiconductor structure comprising a substrate and a dielectric layer, said method comprising the steps of:
forming at least one horizontal patterned metal layer in said dielectric layer, said metal layer comprising an etch stop located over a fixed array area and at least one interconnect for connection to electronic circuitry;
forming a well having vertical walls in said dielectric layer, said well extending through said etch stop; and
forming at least one optical element comprising at least one color filter in said well allowing at least partial transmission of light between a pixel array and the upper vertical limit of said semiconductor structure; and
forming of at least one vertical metal frame within said dielectric layer and in contact with said etch stop such that when said well is formed, said metal frame forms the vertical walls of the well.

14. A method of forming a semiconductor structure, the method comprising:
forming a dielectric layer on a semiconductor substrate; and
forming a plurality of metal layers in the dielectric layer, the plurality of metal layers comprising at least one metal layer adapted to be an etch stop located over an array of pixels.

15. The method of claim 14, wherein the at least one metal layer is formed on substantially a same level as one of the plurality of substantially horizontal metal layers.

16. The method of claim 14, wherein the plurality of metal layers are formed on different levels of the dielectric layer extending from a topmost surface of the substrate to a topmost surface of the dielectric layer, and the at least one metal layer is formed on substantially a same level as one of the plurality of substantially horizontal metal layers.

17. The method of claim 16, wherein the at least one metal layer is formed on substantially a same level as a metal layer formed in closest proximity to the topmost surface of the substrate.

18. The method of claim 16, wherein the at least one metal layer is formed on substantially a same level as a metal layer formed in closest proximity to the topmost surface of the dielectric layer.

19. The method of claim 14, further comprising forming a well extending through the at least one metal layer.

20. The method of claim 19, further comprising forming a material layer within the well.

21. The method of claim 20, wherein the material layer comprises an insulator material.

22. The method of claim 21, wherein the insulator material is transparent.

23. The method of claim 20, wherein the material layer has an index of refraction different from an index of refraction of the dielectric layer.

24. The method of claim 19, further comprising forming a color filter within the well.

25. The method of claim 14, further comprising forming multiple metal layers, each layer comprising a first portion to be used as an etch stop and a second portion to be used as an interconnect or light shield.

26. A semiconductor device, comprising:
a semiconductor substrate having an array of pixels formed therein;
a dielectric layer over the substrate; and
a plurality of metal elements formed within the dielectric layer, wherein a first metal element is formed adjacent to and on substantially a same level as a second metal element used as an interconnect, the first metal element defining a well.

27. The semiconductor device of claim 26, wherein the well defined by the first metal element is substantially aligned with at least one pixel in the array of pixels.

28. The semiconductor device of claim 26, wherein the plurality of metal elements comprises metal elements formed on different levels of the dielectric layer extending from a topmost surface of the substrate to a topmost surface of the dielectric layer.
